(19) United States
(12) Patent Application Publication
(10) Pub. No.: US 2020/0364552 A1
(43) Pub. Date: Nov. 19, 2020

(54) QUANTIZATION METHOD OF IMPROVING THE MODEL INFERENCE ACCURACY

(71) Applicant: Baidu USA LLC, Sunnyvale, CA (US)

(72) Inventor: MIN GUO, Sunnyvale, CA (US)

(21) Appl. No.: 16/411,098

(22) Filed: May 13, 2019

(51) Int. Cl. G06N 3/08; G06N 3/04; G06N 20/20; H03M 7/24

(52) U.S. Cl. CPC G06N 3/08; H03M 7/24; G06N 20/20; G06N 3/0454

(57) ABSTRACT

The disclosure describes various embodiments for quantizing a trained neural network model. In one embodiment, a two-stage quantization method is described. In the offline stage, statically generated metadata (e.g., weights and bias) of the neural network model is quantized from floating-point numbers to integers of a lower bit width on a per-channel basis for each layer. Dynamically generated metadata (e.g., an input feature map) is not quantized in the offline stage. Instead, a quantization model is generated for the dynamically generated metadata on a per-channel basis for each layer. The quantization models and the quantized metadata can be stored in a quantization meta file, which can be deployed as part of the neural network model to an AI engine for execution. One or more specially programmed hardware components can quantize each layer of the neural network model based on information in the quantization meta file.

### TECHNICAL FIELD

Embodiments of the present disclosure relate generally to artificial intelligence (AI) engines. More particularly, embodiments of the disclosure relate to neutral network quantization.

### BACKGROUND

As a branch of artificial intelligence (AI), machine learning can perform a task without using an application specifically programmed for the task. Instead, machine learning can learn from past examples of the given task during a training process, which typically involves learning weights from a dataset.

A trained machine learning model (e.g., a neural network model) can perform a task on input data through inference, and typically uses the 32-bit floating-point representation as the default representation to represent metadata (e.g., weights and bias) of the model. During the inference, input feature maps can be represented in 32-bit integers. The larger bit width of the metadata and the input feature map can significantly impact the performance of the neural network model, as operations with the 32-bit representation tend to be slower than the 8-bit or 16-bit representation, and also use substantially more memory. This can present a problem for deep learning applications running on mobile devices or embedded devices (e.g., drones and watches), where computing resources (e.g., memory, CPU power) are typically limited.

Therefore, techniques have been used to quantize trained neural network models. Quantization is the process of mapping input values from a large set to output values in a smaller set. One example is to map 32-bit integers to 8-bit integers. A quantized neural network model can use less memory consumption, less storage space, can be easier to update and easier to be shared over small-bandwidth connections. However, decreasing bit-widths with quantization generally yields drastically degraded inference accuracy of the quantized neural network model.

### BRIEF DESCRIPTION OF THE DRAWINGS

Embodiments of the disclosure are illustrated by way of example and not limitation in the figures of the accompanying drawings in which like references indicate similar elements.

FIG. 1 illustrates a flow diagram of using a quantized neutral network in accordance with an embodiment.

FIG. 2A and FIG. 2B illustrate an example process of quantizing a particular layer in a convolutional neural network in accordance with an embodiment.

FIG. 3 illustrates an example system for quantizing a neural network model in accordance with an embodiment.

FIG. 4 illustrates an example offline quantization system in accordance with an embodiment.

FIG. 5 illustrates an example offline quantization process in accordance with an embodiment.

FIG. 6 further illustrates an example online quantization process in accordance with an embodiment.

FIGS. 7A-7C illustrate an example process of quantizing metadata of a neural network model in accordance with an embodiment.

FIG. 8 illustrates a flow diagram illustrating an example process of quantizing a neural network in accordance with an embodiment.

FIG. 9 illustrates a flow diagram illustrating another example process of quantizing a neural network in accordance with an embodiment.

FIG. 10 is a block diagram illustrating an example of a data processing system which may be used with one embodiment.

### DETAILED DESCRIPTION

Various embodiments and aspects of the disclosures will be described with reference to details discussed below, and the accompanying drawings will illustrate the various embodiments. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosures.

Reference in the specification to “one embodiment” or “an embodiment” means that a particular feature, structure, or characteristic described in conjunction with the embodiment can be included in at least one embodiment of the disclosure. The appearances of the phrase “in one embodiment” in various places in the specification do not necessarily all refer to the same embodiment.

The disclosure describes various embodiments for quantizing a trained neural network model. In one embodiment, a two-stage quantization method is described. In the offline stage, statically generated metadata (e.g., weights and bias) of the neural network model is quantized from floating-point numbers to integers of a lower bit width on a per-channel basis for each layer. Dynamically generated metadata (e.g., an input feature map) is not quantized in the offline stage. Instead, a quantization model is generated for the dynamically generated metadata on a per-channel basis for each layer. The quantization models and the quantized metadata can be stored in a quantization meta file, which can be deployed as part of the neural network model to an AI engine for execution. One or more specially programmed hardware components can quantize each layer of the neural network model based on information in the quantization meta file.

In one embodiment, the offline quantization tool can perform multiple inferences using the neural network model on a subset of data extracted from a training data, and generate a data distribution for an input feature map per channel per layer. Based on the data distribution, the offline quantization tool can remove outlier values to determine a minimum floating value and a maximum floating-point value for each channel at each layer. Corresponding integers of the same bit width with the maximum floating-point value and the minimum floating-point value can also be determined. The offline quantization tool can generate a quantization model for the input feature map for each channel of each layer based on the maximum floating-point value and the maximum integer, the minimum floating-point value and the minimum integer, and an integer type of a lower bit width. The quantization models can be used to quantize input features maps when the neural network model is running on an AI engine.

In one embodiment, the quantized neural network model can be deployed on an integrated circuit including a number of hardware components configured to execute instructions to perform one or more operations of the quantized neural network model. For example, an accumulator hardware component can be programmed to accumulate outputs of a quantized layer of the trained neural network and add quantized channel biases the outputs, to generate floating-point outputs for the layer. A scaler hardware component can be programmed to rescale the floating-point outputs of the layer back to the integer representation (e.g., 8-bit representation) back using the quantization models for that layer before feeding the outputs to the next layer as inputs.

In one embodiment, the weights and bias per channel per layer are quantized offline. In quantizing weights and bias per channel for each layer of the neural network model, the offline quantization tool can generate a data distribution of floating-point values based on multiple inferences performed. One or more outliers from each end of the normal distribution can be removed, an upper bound and a lower bound of the normal distribution without the outliers can be determined, and a closest integer corresponding integer to a zero in the floating-point representation can be identified. With the upper bound, the lower bound, and the closest integer, the offline quantization tool can execute a predetermined algorithm to map each float-pointing value between the upper bound and the lower bound to an integer, e.g., between 0 and 255 in the 8-bit representation.

Compared with the existing quantization techniques that quantize weights only and at a layer level, the per-channel quantization approach described in this disclosure can improve inference accuracy over per-layer quantization. The per-layer quantization approach, by lumping all the Gaussian distributions for all the channels at each layer, would cause a loss of inference accuracy, because each channel may have a different Gaussian distribution and the distribution for a channel may be different from an entire feature map or another channel. The computing cost associated channel-wise quantization and re-quantization can be reduced by the usage of specialized hardware and by executing the channel-wise quantization and re-quantization in parallel with the entire feature map quantization on an AI engine.

Therefore, the embodiments in the disclosure can provide systems and methods that can improve inference accuracy of quantization for neural network models over existing quantization techniques without degradation the inference speed.

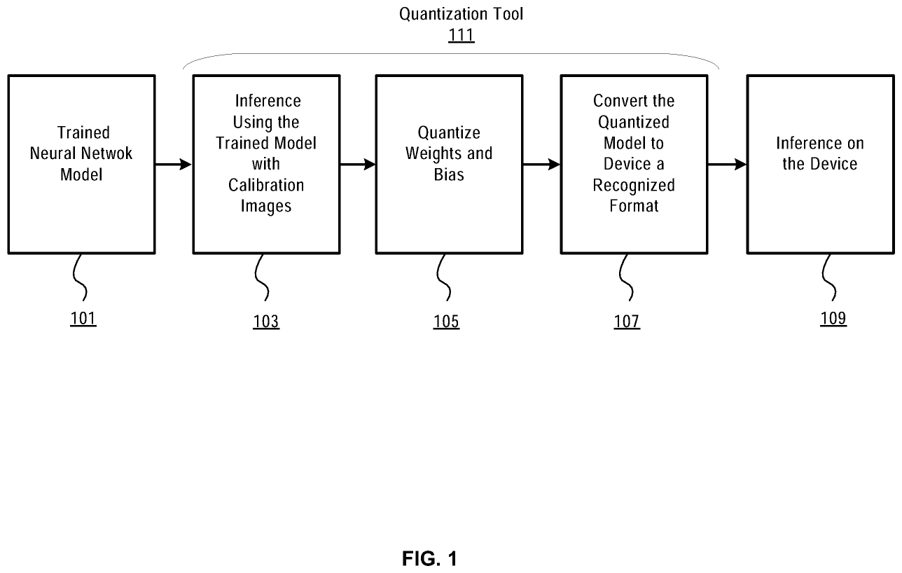

FIG. 1 illustrates an example flow diagram of using a quantized neutral network model in accordance with an embodiment. As shown in the figure, at stage 101, a neural network model can be trained using an offline quantization tool, such as Caffee FP32. At stage 103, a quantization tool 111 can be used to perform inferences on calibration images using the neural network model. For example, a large set of images can be provided as inputs to the neural network model, which can generate data distribution for weights and bias for each layer, for example, each convolutional layer in a convolutional neural network model. At stage 105, the quantization tool 111 can quantize the weights in the data distributions from a floating-point representation to an integer representation (e.g., 8-bit or 16-bit representation). At stage 107, the quantized neural network model can be converted to a format recognizable to a device that the quantized neural network model is to be deployed. At the last stage 109, inferences can be performed on input data using the neural network model.

As describe above, arithmetic operations with a lower bit-depth tend to be faster. For example, operations with 8-bit or 16-bit integers tend to be faster than operations with 32-bit floating-point numbers. Therefore, the quantized neural network model would use less memory, less storage space, can be easier to share over small-bandwidth connections, and can be easier to update.

However, the example flow diagram illustrates a use case where only weights and bias of each layer of the neural network model are quantized. Although this approach can have the benefits mentioned above (e.g., less memory usage), the inference accuracy of the quantized neural network model may suffer.

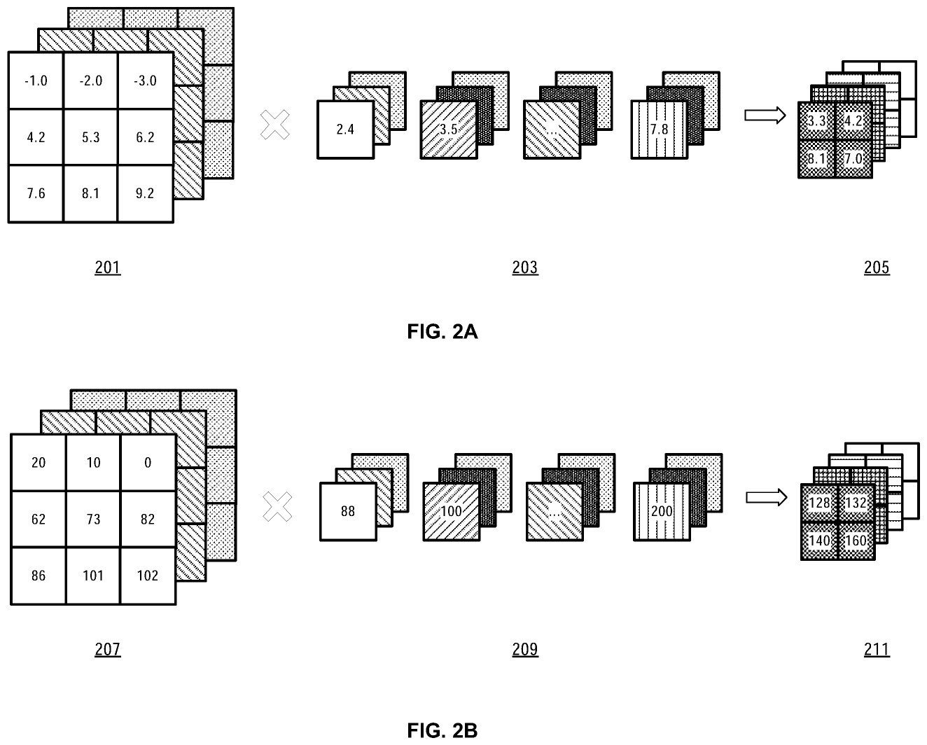

FIG. 2A and FIG. 2B illustrate an example process of quantizing a particular layer in a convolutional neural network in accordance with an embodiment.

A convolutional neural network (CNN) can include multiple convolutional (CONV) layers and one or more fully-connected (FC) layers. With each CONV layer, a higher-level abstraction of the input data can be extracted to preserve essential yet unique information of the input data. The higher-level abstraction of the input data is a feature map extracted from the input data.

Each layer can take one or more feature maps as an input and generate one or more output feature maps, which in turn can be provided to a next layer as input feature maps. The output feature maps of the final CONV layer in the neural network model can be processed by the FC layers for classification purposes. Between the CONV layers and the FC layers, additional layers can be added, such as pooling and normalization layers. Each CONV layer or FC layer can also be followed by an activation layer, such as a rectified linear unit (ReLU).

Referring to FIG. 2A, a number of kernels (i.e. filters) 203 can be applied to the input feature maps 201 of an input image. The kernels 203 are applied globally across the whole input image to produce a matrix of outputs 205.

In one embodiment, as used herein, a filter can be represented by one or more weights (e.g., 2.4, 3.5, or 7.8), and provide a measure of how close a patch of input resembles a feature. Examples of features can include a vertical edge or an arch. The feature thus identified not handcrafted features but derived from the data through a learning algorithm. A filter can be used to convolve an input to a CONV layer. Convolving a layer means multiplying the weights of each filter by pixel values of the input feature maps and adding products up to produce a tensor of outputs. If a bias is used, the bias may be added to the outputs.

In one embodiment, as used herein, a bias node for each layer in a neural network model is a node that is always on, and has a value of 1 without regard for the data in a given pattern. A bias node is analogous to the intercept in a regression model, and can serve the same function. Without a bias node in a given layer, a neural network model would not be able to produce output in the next layer that differs from 0 when the feature values are 0.

In FIG. 2A, the input feature map 201 includes 3 channels, i.e., red, green and blue (RGB) channels. Subsequent layers can operate on 3-D representation of the data, where the first two dimensions can be the height and width of an image patch, and the third dimension is a number of such patches (i.e., red, green, and blue) stacked over one another. As the number of filters used to convolve the subsequent layers changes, the number of channels associated with each subsequent layer can also change.

In FIG. 2A, the input feature maps 201, the kernels 203, and the output feature maps 205, are all in the floating-point representation. FIG. 2B shows that the layer illustrated in 2A are quantized, with input feature maps 207, kernels 209 and output feature maps 211 reduced to an integer representation.

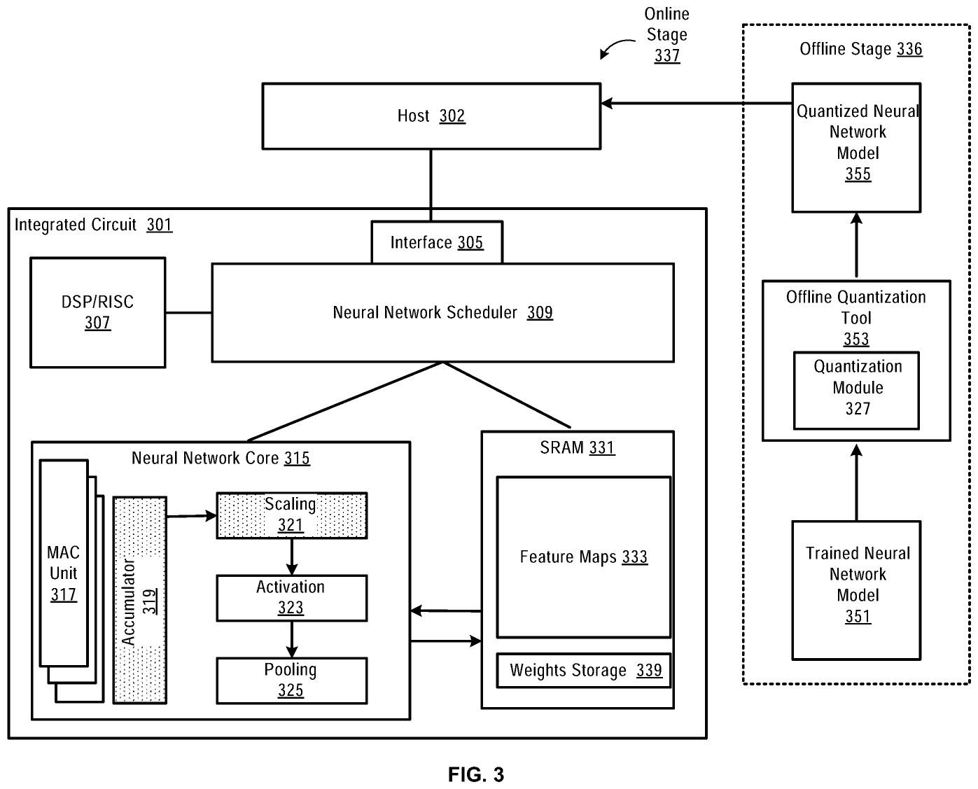

FIG. 3 illustrates an example system for quantizing a neural network model in accordance with an embodiment. As shown, quantizing a neural network model (e.g., a CNN model) can include an offline stage 336 and an online stage 337. For the offline stage 336, an offline quantization tool 353 with a quantization module 327 quantizes a trained neural network model 351 at a channel level for each layer of the neural network.

As described above, each convolutional layer of of a trained CNN can be associated with metadata. Some metadata (e.g., weights and bias) are statically generated during the training of the CNN, while other metadata (e.g., input feature maps and output feature maps) are dynamically generated, and are not part of the trained neural network. The dynamically generated metadata is not available before the trained neural network is deployed to a device (e.g. a graphics processing unit or GPU, or an AI engine) for inferencing with an input image. During the offline inferencing, the metadata associated with each layer are in a floating-point (e.g., 32-bit) representation.

In one embodiment, during the offline state 336, the trained neural network model 351 can be deployed to a GPU for inferencing with a number of images to generate a quantization model for each metadata for each channel of each layer. The offline quantization tool 352 can store each quantization model in a quantization meta file, which can be deployed to an AI engine as part of the quantized neural network model.

In one embodiment, the quantization model for a statically generated metadata (e.g., weights or bias) at each channel can include the quantization metadata and one or more debugging parameters. An example quantization model for weights can be show as follows: {ch₀, fₘᵢₙ, fₘₐₓ, type(signed Aug. 12, 2016, unsigned Aug. 12, 2016), quant_data}, where the “ch₀” represents a channel indicator, the “fₘᵢₙ” and “fₘₐₓ” represent a range of the metadata, the “quant_data” represents the quantized metadata, and the “type(signed Aug. 12, 2016, unsigned Aug. 12, 2016)” indicates the type of integers that the original floating-point metadata has been quantized to. In this example, the type of integers can be 8-bit, 12-bit or 16-bit.

For a dynamically generated metadata (e.g., one or more feature maps) at each channel, the quantization model can include a set of parameters that enable an AI engine to quantize the metadata at that channel. An example quantization model for an input feature map at a particular channel can be represented by the following set of parameters: {ch₀, fₘᵢₙ, fₘₐₓ, type (signed Aug. 12, 2016, unsigned Aug. 12, 2016), int_min, int_max}.

In the above parameter set, the “ch₀” is the numerical indicator of the channel (e.g., the 1st channel, the 2nd channel, etc.), the “fₘᵢₙ” and “fₘₐₓ” represent a value range of the per-channel distribution of floating-point values, the “int_min” and “int_max” are integers that correspond respectively to the “fₘᵢₙ” and “fₘₐₓ”, and the “type(signed Aug. 12, 2016, unsigned Aug. 12, 2016)” indicates the type of integers that the input feature map would be quantized to.

In one embodiment, the example quantization mode is used by an integrated circuit 301 to quantize the corresponding metadata when the neural network model is executed in an online mode. In one example, the integrated circuit 301 can quantize 32-bit integers within the “int_min:” and the “int_max” to lower-bit integers (e.g., 8-bit, 12-bit, or 16-bit).

As further shown in FIG. 3, in the online stage 337, the quantized neural network model 355 can be deployed to the integrated circuit 301, which has a neural network core 315 and one or more processors, for example, a reduced instruction set computer (RISC) or a digital signal processor (DSP) 307. The neural network core 315 can be an independent processing unit that includes multiple multiply-accumulate (MAC) units (e.g., 256 MAC units), each MAC unit (e.g., MAC unit 117) including multiple processing elements (PE).

In one embodiment, the quantized neural network model 355, together with the quantization meta file describing the quantization, can be deployed on a host 302. During runtime, a neural network scheduler 309 can retrieve one or more mapping metafile via an interface 305, and use mapping information in the metafiles to allocate MAC units from the neural network core 315 to execute at least one operation of the quantized neural network model 355.

In one embodiment, the integrated circuit 101 can include a SRAM 331 to store feature maps 333 of the trained neural network model 355. The SRAM 331 can store input feature map slices, output feature map slices, and weights 339 for the current layer. As the execution of the quantized neural network model 355 progresses to a next layer, weights for the next layer can be retrieved from an external storage (e.g., a DDR memory) on the host 302 or another external storage, and loaded into the SRAM 331.

In one embodiment, the neural network core 315 can include hardware components that are programmed to execute a particular portion of the quantized neural network model 355. For example, the neural network core 315 can include an accumulator component or logic 319, a scaling component or logic 321, an activation component or logic 323, and a pooling component or logic 325. The accumulator 319 is programmed to accumulate per-channel outputs from a convolutional layer of the quantized neural network model 355 and then add the quantized per-channel bias for that layer to generate a result in a 32-bit integer representation. The scaling component 321 is programmed to rescale the 32-bit integer output feature map back to an 8-bit or 16-bit integer representation based on the corresponding input feature map quantization model described in the quantization meta file.

In one embodiment, the scaling component (i.e. scaler) 321 can implement a quantization algorithm to reduce higher-precision integers to a lower-precision integers. An example algorithm used to reduce 32-bit integers to 8-bit integers can be illustrated as follows:

1). Range of lower-precision integers:
Quant INT8 = (Xmin_int8, Xmax_int8) = (0, 255)
2). Range of high-precision integer obtained from the
corresponding quantization model Xint32 range =
(Xmin_int32, Xmax_int32)
3). Scale
Xscale = (Xmax_int32 − Xmin_int32)/(Xmax_int8 − Xmin_int8) =
(Xmax_int32 − Xmin_int32)/255
4). Corresponding zero
Xzero_int8 = Xmax_int8 − Xmax_int32/Xscale = 255 − Xmax_int32/
Xscale
5). Corresponding lower-precision integer to a higher-precision
integer in a feature map Xquant = Xint_32/Xscale + Xzero_int8 =
(any value in the output fmap)/Xscale + Xzero_int8

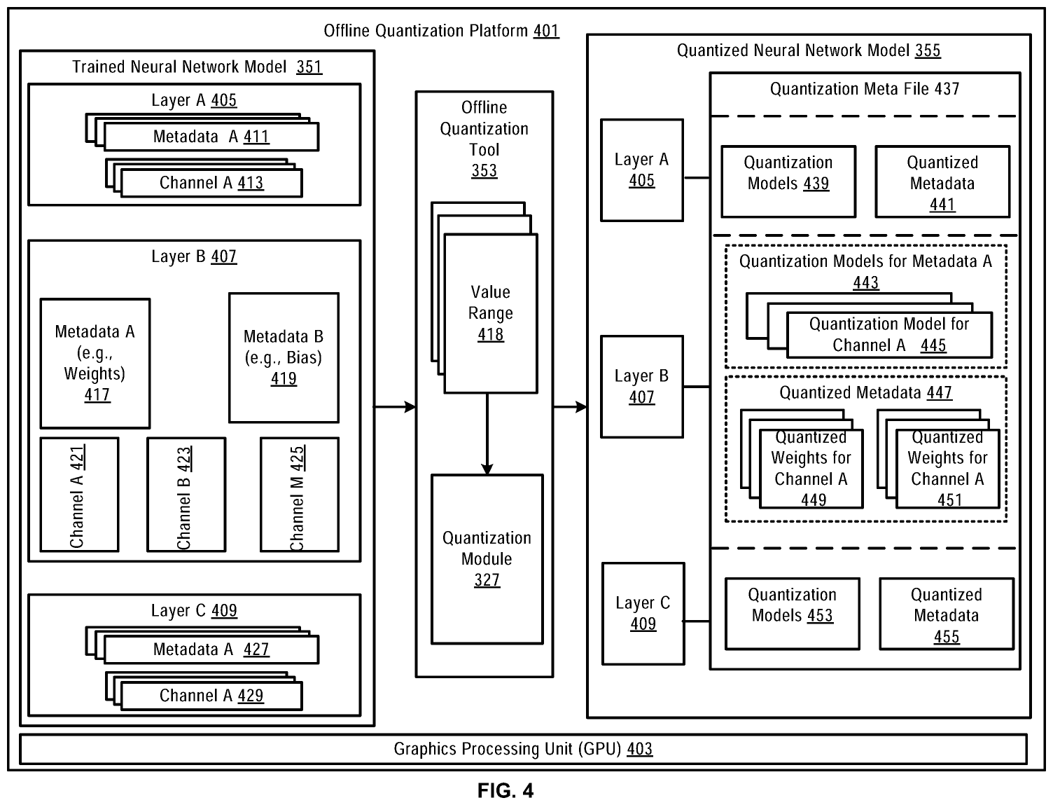

FIG. 4 illustrates an example offline quantization system in accordance with an embodiment. In one embodiment, an offline quantization platform 401 can include the offline quantization tool 353 executing on a GPU 403. The quantization module 327 in the offline quantization can implement a predetermined quantization algorithm to generate per-channel per-layer quantization models based on a number of inferences performed by the neural network model 351 with a subset of data from a data set. A portion of the data set can be used to train the neural network model 351 and another portion of the data set can be used to evaluate and validate the neural network model 351. The extracted subset of data can be used to generate a data distribution for each metadata per-channel and per-layer. The data distribution can be the basis for creating a quantization model for each channel of each layer of the neural network model 351.

In one embodiment, as an illustrative example, the offline quantization tool 353 can generate data distributions for an input feature map at a particular channel. Outlier values from the data distribution can then be removed. A minimum floating-point number (fₘᵢₙ) and a maximum floating-point number (fₘₐₓ) can be identified from the data distribution. In one example, the fₘᵢₙ and fₘₐₓ are both 32-bit floating-point numbers. The offline quantization tool 353 can use the fₘᵢₙ and the fₘₐₓ to identify their corresponding values or ranges in the 32-bit integer representation.

Based on the minimum floating-point number (fₘᵢₙ), the maximum floating-point number (fₘₐₓ), their corresponding integers of the same bit width, and an integration type of a lower bit width (e.g., 8-bit), the offline quantization tool 353 can generate a quantization model for the input feature map at the channel.

Referring back to FIG. 4, the neural network model 351 can include three CONV layers, for example, layer A 405, layer B 407, and layer C 409. Each layer can include metadata and a number channels. For example, layer A can include metadata A 413 and channel A 413 in layer A 405, and layer C 409 can include metadata A 427 and channel A 429.

As shown in FIG. 4, a number of quantization models 439 and one or more quantized metadata 441 can be generated for layer A 405 by the offline quantization tool 353, and can be stored in a quantization meta file 437. Similarly, for layer C 409, the offline quantization tool 353 can also generate a number of quantization models 453 and one or more quantized metadata 455 can be generated for layer C 409

FIG. 4 uses layer B 407 to illustrate in detail quantization models and quantized metadata created by the offline quantization tool 353. Layer B includes metadata A 415 and metadata B 417, each of which can be statically generated when the neutral network model 351 is trained, and can be in 32-bit floating-point representation. Layer B also includes a number of channels 421, 423, and 425.

In one embodiment, the offline quantization model 353 can store a number of value ranges (e.g., value range 418) obtained from data distributions generated from a number of inferences performed by the neural network model 351 on the subset of data from a data set.

Based on the value ranges, the offline quantization tool 353 can generate a number of quantization models 443 for metadata A, including a quantization model (e.g., quantization model 445) for each of the channels 421, 423, and 425. Based on the value ranges, the offline quantization tool 353 can also generate quantized metadata 447 for Layer B 407, including quantized weights (e.g., quantized weights 449) per channel and quantized bias (e.g., quantized bias 451) per channel.

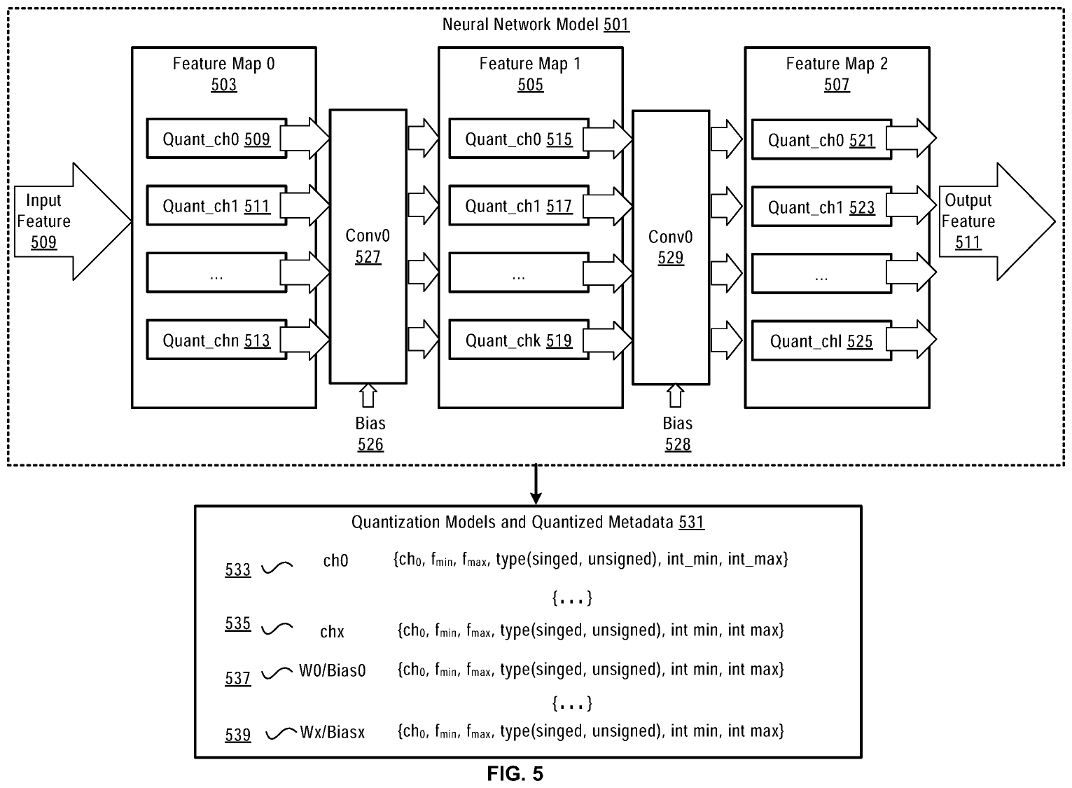

FIG. 5 illustrates an example offline quantization process in accordance with an embodiment. In this example process, all layers and their associated metadata are in the 32-bit floating-point representation, and an offline quantization tool such as the quantization tool 353 described above can be used to quantize weights and bias per channel for each layer to the 8-bit integer representation.

As shown in FIG. 4, a neural network model 501 can include a CONV layer 527 and a CONV layer 529. The neural network model 501 can have an input feature 509 and an output feature 511. Each CONV layer can have an input feature map and an output feature map 503, 505 and 507. Each feature map have be associated a number of channels. For example, the feature map 503 can be associated with channels 509-513, the feature map 505 can be associated with channels 515-519, and the feature map 507 can be associated with channels 421-523. In addition, each channel for each CONV layer can have weights (not shown) and bias 526 and 528.

Based on a number of inferences performed by the neural network model 510 on a predetermined data set, the offline quantization tool can generate a number of quantization models for each input feature map, and a number of quantized of metadata.

Quantized models and quantized metadata 531 illustrates some examples of the quantization models and quantized metadata. The examples shown in FIG. 5 are for one layer of the neutral network model 501, and therefore represent a subset of the quantization models and quantized metadata generated by the offline quantization tool. As shown, a quantization model 533 and 535 for each channel for the layer is generated. Similarly, quantized weights and quantized bias 535 and 537 can also be generated.

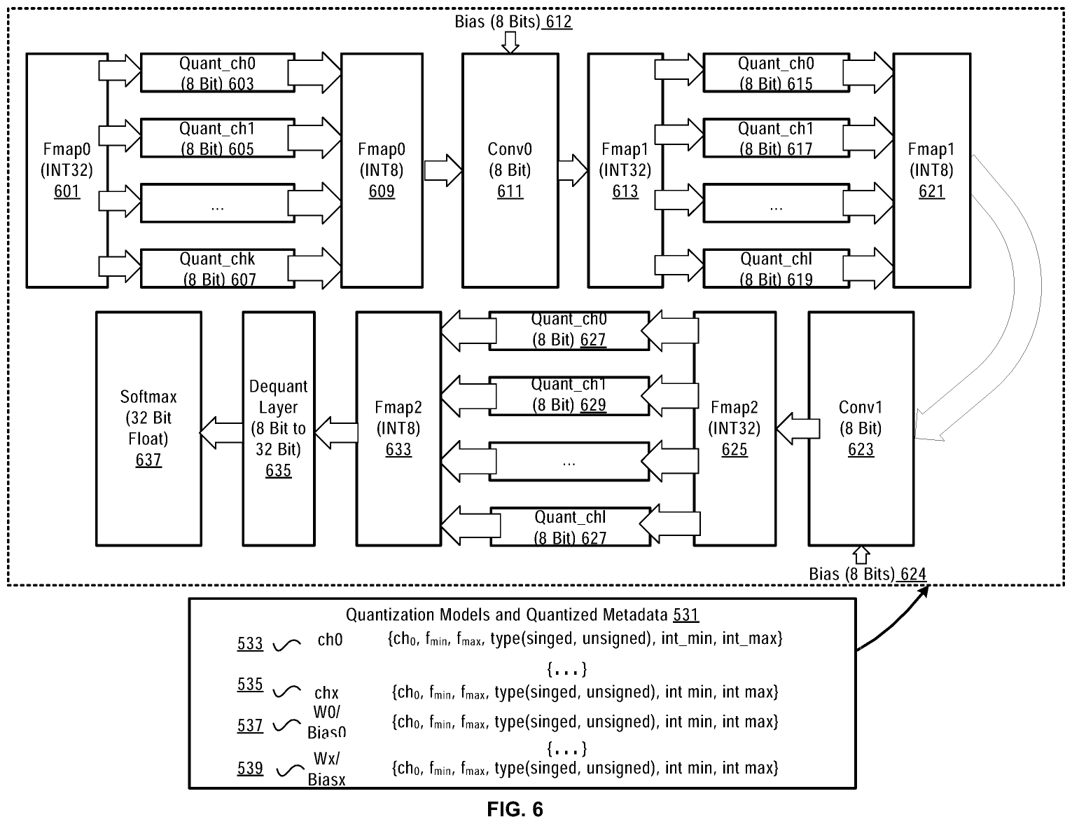

FIG. 6 further illustrates an example online quantization process in accordance with an embodiment. As shown in the figure, when a quantized neural network model (e.g., quantized neural network model 355 in FIG. 4) is deployed to an AI engine, the neural network model can use the quantization meta file and the specially programmed hardware components to quantize the input feature map for each layer for each channel of the layer.

In the example shown in FIG. 6, the neural network model includes a convolutional layer 611 and a convolutional layer 623. An input feature map 601 to the convolutional layer 611 is represented by 32-bit integers. Therefore, the input feature map 601 is to be quantized to an 8-bit feature map 609 per channel 603, 605 and 607, using metadata 531 corresponding to the respective channel of the respective layer of the model, before being fed to the convolutional layer 611. A bias 612 is also quantized to the 8-bit representation. That, for each channel, the 32-bit data is scaled down to 8-bit data using the minimum integer value and the maximum integer value as scaling factors to ensure that the quantized data is within the respective range for that particular channel of that particular layer of the model. Similarly, when scaling 32-bit data 635 to floating point values 637, the metadata maximum and minimum floating point values as a part of metadata corresponding to the channel of the corresponding layer are utilized to maintain the output is within an expected range. As a result, a neural network model, which is normally processed using floating points, can be carried out using integer units of an integrated circuit or processor. The calculation in integers can be performed much faster than floating point calculation.

As shown, a corresponding output feature map 613 is converted to the 32-bit integer representation by the convolutional layer 611, and needs to be scaled back to the 8-bit representation per channel 615, 617 and 619 as an 8-bit feature map 621 before being fed to the convolutional layer 623, where a bias 624 is also quantized.

Similarly, the output of the convolutional layer 623 is a 32-bit integer output feature map 625, which would again be scaled back to an 8-bit integer feature map 633 per channel 631, 629 and 627. The 8-bit integer feature map 633 can be re-quantized from 8-bit to 32-bit before being fed to a CPU that supports RISC or 32-bit floating-point values (FP32).

In one embodiment, the information in the quantization models and quantized metadata 531 can be loaded into memory of the AI engine and use to support the quantization and re-quantization described above.

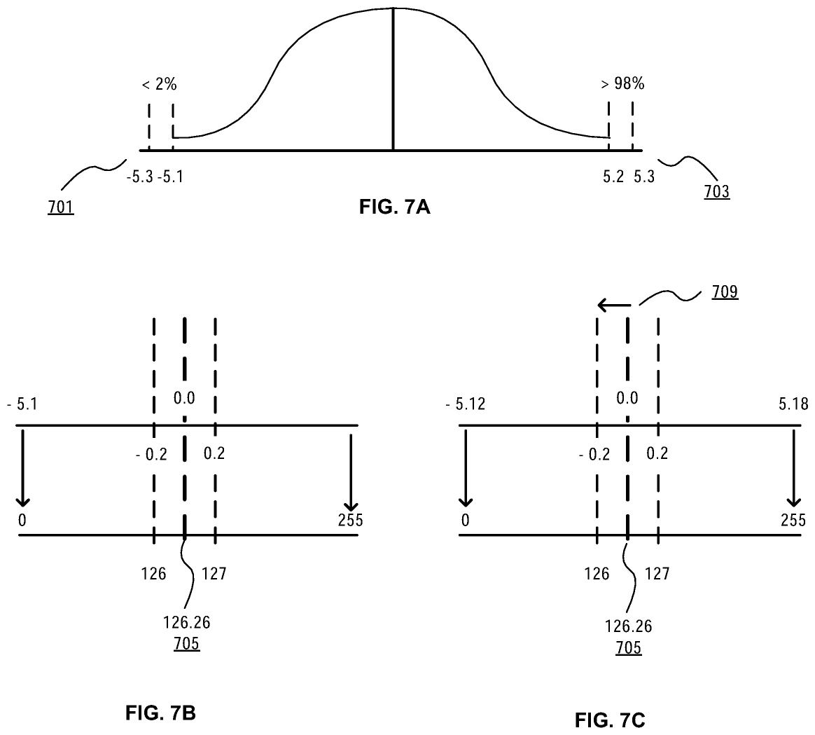

FIGS. 7A-7C illustrate an example process of quantizing metadata of a neural network model in accordance with an embodiment. In one example, the example process can be used to quantize weights and bias of a neural network model.

FIG. 7A is a data distribution of a metadata of the neural network model. Based on the distribution, outlier values 701 and 703 below 2% and above 98% can be removed to get an fₘᵢₙ and an fₘₐₓ. In this example, the outliers in [−5.3, −5.1] and [5.2, 5.3] are removed. Accordingly, the fₘᵢₙ and fₘₐₓ are respectively −5.1 and 5.2, with the input range being [−5.1, 5.2].

For the above input range, the encoding range is 5.2−(−5.1)=10.3, and the step size is 10.3/255=0.04 (assuming that the input range is to be quantized to the 8-bit representation).

As shown in FIG. 7B, the zero value is currently not representable in the 8-bit integer representation. The closest values that are representable in the 8-bit integer representation are −0.02 and +0.02, which can be represented integers of 126 and 127 respectively.

In this example, values 126 and 127 are the appropriate integer numbers of 125.7 and 126.7 respectively. The integer 126 is calculated by rounding (255*(−0.2+5.1)/(5.2+5.1), and the integer 127 is calculated by rounding (255*(−0.02+5.1)/(5.2+5.1)).

In FIG. 7C, the fₘᵢₙ of 5.1 and the fₘₐₓ of 5.2 are slightly shifted 709 to the left to make the floating-point zero exactly representable. The shifting transforms the fₘᵢₙ of 5.1 and the fₘₐₓ of 5.2 to −5.12 and 5.18 respectively. The input range can be quantized to integers within the range 0 and 255 using the example quantization formula: quantized value=round (255*(floating-point value−fₘᵢₙ)/(fₘₐₓ−fₘᵢₙ)).

The fₘᵢₙ of 5.1 and the fₘₐₓ of 5.2 are shifted left by 0.2 because the value of 0 in the floating-point representation corresponds to (255*(0+5.1)/10.3)=126.26, which can be rounded to 126. The corresponding integer of the floating-point zero is closer to that of −0.02 (125.7 rounded to 126) than that of 0.02(126.7 rounded 127). In one embodiment, the corresponding integer of a floating-point value can be an integer in the 8-bit or 16-bit representation that is rounded from an approximate number. After the shifting, the floating-point zero would be encoded to the integer 126.

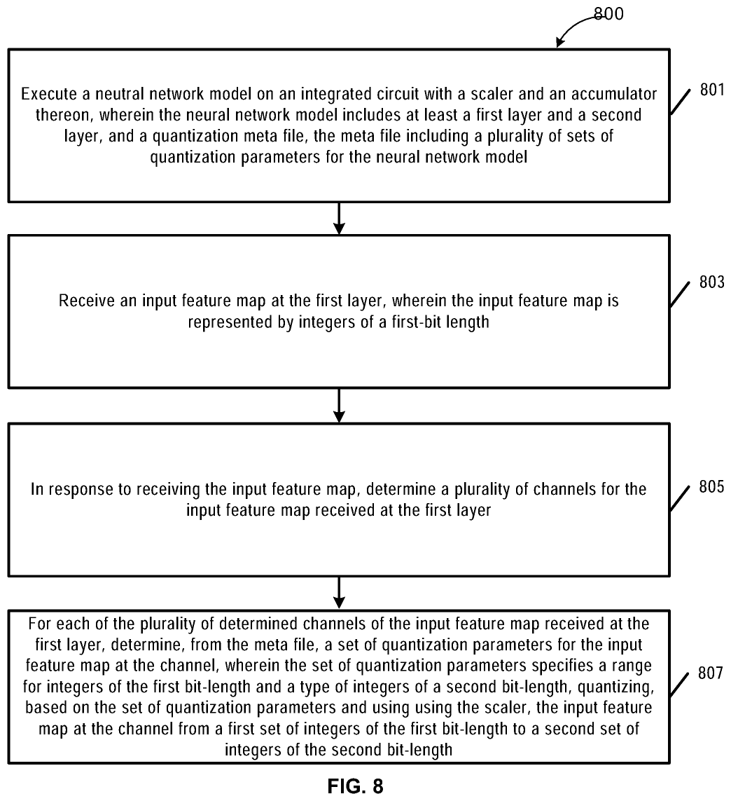

FIG. 8 illustrates a flow diagram illustrating an example process of quantizing a neural network in accordance with an embodiment. Process 800 may be performed by processing logic which may include software, hardware, or a combination thereof. Process 800 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. In some embodiments, process 600 may be performed by one or more of components, e.g., the integrated circuit 301 in FIG. 3.

In one embodiment, FIG. 7 illustrates a process of how an AI engine executes a trained neural network that has been quantized by an offline quantization tool. After the neural network model is quantized using an offline quantization tool, a quantization meta file can be generated. The quantization meta file includes quantized weights and bias as well as quantization models for input feature maps per channel per layer. One or more hardware components are specifically programmed to process the types of operations as specified by the quantization meta file.

Referring to FIG. 8, in operation 801, a neutral network model is executed on an integrated circuit with a scaler and an accumulator thereon, wherein the neural network model includes at least a first layer and a second layer, and a quantization meta file, the meta file including a plurality of sets of quantization parameters for the neural network model. In operation 803, an input feature map is received at the first layer, wherein the input feature map is represented by integers of a first bit width. In operation 805, in response to receiving the input feature map, a plurality of channels are determined for the input feature map received at the first layer. In operation 809, for each of the plurality of determined channels of the input feature map received at the first layer, a set of quantization parameters is determined from the meta file for the input feature map at the channel, wherein the set of quantization parameters specifies a range for integers of the first bit width and a type of integers of a second bit width, quantizing, based on the set of quantization parameters and using using the scaler, the input feature map at the channel from a first set of integers of the first bit width to a second set of integers of the second bit width.

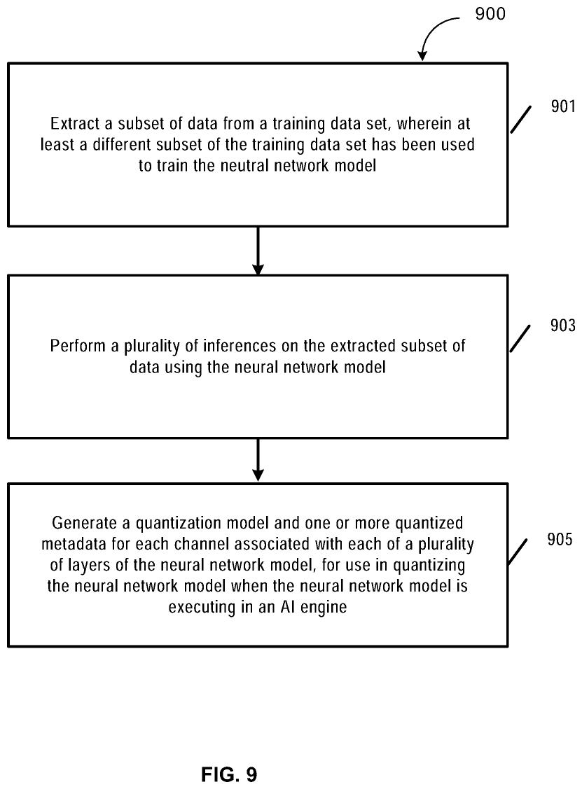

FIG. 9 illustrates a flow diagram illustrating another example process of quantizing a neural network in accordance with an embodiment.

Process 900 may be performed by processing logic which may include software, hardware, or a combination thereof. Process 900 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. In some embodiments, process 900 may be performed by one or more of components, such as the offline quantization tool 353 in FIG. 3.

Referring to FIG. 9, in operation 901, the processing logic extracts a subset of data from a training data set, wherein at least a different subset of the training data set has been used to train the neutral network model. In operation 903, the processing logic performs a plurality of inferences on the extracted subset of data using the neural network model. In operation 905, the processing logic generates a quantization model and one or more quantized metadata for each channel associated with each of a plurality of layers of the neural network model, for use in quantizing the neural network model when the neural network model is executing in an AI engine.

Note that some or all of the components as shown and described above may be implemented in software, hardware, or a combination thereof. For example, such components can be implemented as software installed and stored in a persistent storage device, which can be loaded and executed in a memory by a processor (not shown) to carry out the processes or operations described throughout this application. Alternatively, such components can be implemented as executable code programmed or embedded into dedicated hardware such as an integrated circuit (e.g., an application specific IC or ASIC), a digital signal processor (DSP), or a field programmable gate array (FPGA), which can be accessed via a corresponding driver and/or operating system from an application. Furthermore, such components can be implemented as specific hardware logic in a processor or processor core as part of an instruction set accessible by a software component via one or more specific instructions.

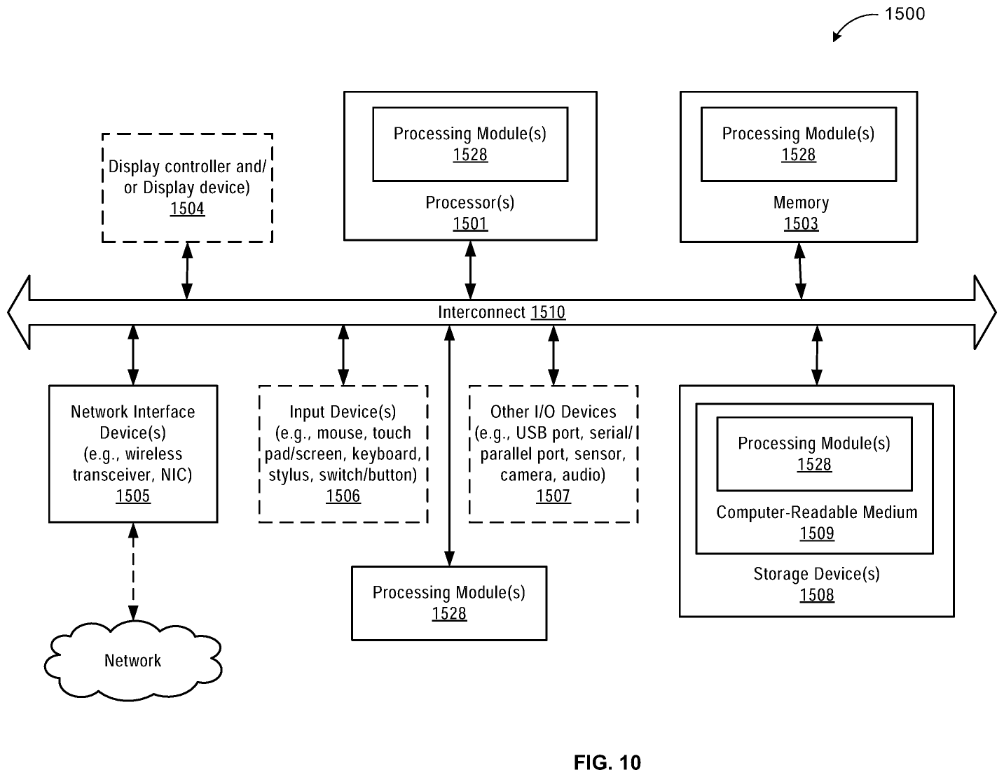

FIG. 10 is a block diagram illustrating an example of a data processing system which may be used with one embodiment of the disclosure. For example, system 1500 may represent any of data processing systems described above performing any of the processes or methods described above. System 1500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system.

System 1500 is intended to show a high level view of many components of the computer system. However, it is to be understood that additional components may be present in certain implementations and furthermore, different arrangement of the components shown may occur in other implementations. System 1500 may represent a desktop, a laptop, a tablet, a server, a mobile phone, a media player, a personal digital assistant (PDA), a Smartwatch, a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 1500 includes processor 1501, memory 1503, and devices 1505-1508 connected via a bus or an interconnect 1510. Processor 1501 may represent a single processor or multiple processors with a single processor core or multiple processor cores included therein. Processor 1501 may represent one or more general-purpose processors such as a microprocessor, a central processing unit (CPU), or the like. More particularly, processor 1501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 1501 may also be one or more special-purpose processors such as an application specific integrated circuit (ASIC), a cellular or baseband processor, a field programmable gate array (FPGA), a digital signal processor (DSP), a network processor, a graphics processor, a communications processor, a cryptographic processor, a co-processor, an embedded processor, or any other type of logic capable of processing instructions.

Processor 1501, which may be a low power multi-core processor socket such as an ultra-low voltage processor, may act as a main processing unit and central hub for communication with the various components of the system. Such processor can be implemented as a system on chip (SoC). Processor 1501 is configured to execute instructions for performing the operations and steps discussed herein. System 1500 may further include a graphics interface that communicates with optional graphics subsystem 1504, which may include a display controller, a graphics processor, and/or a display device.

Processor 1501 may communicate with memory 1503, which in one embodiment can be implemented via multiple memory devices to provide for a given amount of system memory. Memory 1503 may include one or more volatile storage (or memory) devices such as random access memory (RAM), dynamic RAM (DRAM), synchronous DRAM (SDRAM), static RAM (SRAM), or other types of storage devices. Memory 1503 may store information including sequences of instructions that are executed by processor 1501, or any other device. For example, executable code and/or data of a variety of operating systems, device drivers, firmware (e.g., input output basic system or BIOS), and/or applications can be loaded in memory 1503 and executed by processor 1501. An operating system can be any kind of operating systems, such as, for example, Robot Operating System (ROS), Windows® operating system from Microsoft®, Mac OS®/iOS® from Apple, Android® from Google®, LINUX, UNIX, or other real-time or embedded operating systems.

System 1500 may further include 10 devices such as devices 1505-1508, including network interface device(s) 1505, optional input device(s) 1506, and other optional 10 device(s) 1507. Network interface device 1505 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 1506 may include a mouse, a touch pad, a touch sensitive screen (which may be integrated with display device 1504), a pointer device such as a stylus, and/or a keyboard (e.g., physical keyboard or a virtual keyboard displayed as part of a touch sensitive screen). For example, input device 1506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 1507 may include an audio device. An audio device may include a speaker and/or a microphone to facilitate voice-enabled functions, such as voice recognition, voice replication, digital recording, and/or telephony functions. Other IO devices 1507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. Devices 1507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 1510 via a sensor hub (not shown), while other devices such as a keyboard or thermal sensor may be controlled by an embedded controller (not shown), dependent upon the specific configuration or design of system 1500.

To provide for persistent storage of information such as data, applications, one or more operating systems and so forth, a mass storage (not shown) may also couple to processor 1501. In various embodiments, to enable a thinner and lighter system design as well as to improve system responsiveness, this mass storage may be implemented via a solid state device (SSD). However in other embodiments, the mass storage may primarily be implemented using a hard disk drive (HDD) with a smaller amount of SSD storage to act as a SSD cache to enable non-volatile storage of context state and other such information during power down events so that a fast power up can occur on re-initiation of system activities. Also a flash device may be coupled to processor 1501, e.g., via a serial peripheral interface (SPI). This flash device may provide for non-volatile storage of system software, including BIOS as well as other firmware of the system.

Storage device 1508 may include computer-accessible storage medium 1509 (also known as a machine-readable storage medium or a computer-readable medium) on which is stored one or more sets of instructions or software (e.g., module, unit, and/or logic 1528) embodying any one or more of the methodologies or functions described herein. Processing module/unit/logic 1528 may represent any of the components described above, such as, for example, the offline quantization tool 353. Processing module/unit/logic 1528 may also reside, completely or at least partially, within memory 1503 and/or within processor 1501 during execution thereof by data processing system 1500, memory 1503 and processor 1501 also constituting machine-accessible storage media. Processing module/unit/logic 1528 may further be transmitted or received over a network via network interface device 1505.

Computer-readable storage medium 1509 may also be used to store the some software functionalities described above persistently. While computer-readable storage medium 1509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media, or any other non-transitory machine-readable medium.

Processing module/unit/logic 1528, components and other features described herein can be implemented as discrete hardware components or integrated in the functionality of hardware components such as ASICS, FPGAs, DSPs or similar devices. In addition, processing module/unit/logic 1528 can be implemented as firmware or functional circuitry within hardware devices. Further, processing module/unit/logic 1528 can be implemented in any combination hardware devices and software components.

Note that while system 1500 is illustrated with various components of a data processing system, it is not intended to represent any particular architecture or manner of interconnecting the components; as such details are not germane to embodiments of the present disclosure. It will also be appreciated that network computers, handheld computers, mobile phones, servers, and/or other data processing systems which have fewer components or perhaps more components may also be used with embodiments of the disclosure.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the disclosure also relate to an apparatus for performing the operations herein. Such a computer program is stored in a non-transitory computer readable medium. A machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments of the present disclosure are not described with reference to any particular programming language. It will be appreciated that a variety of programming languages may be used to implement the teachings of embodiments of the disclosure as described herein.

In the foregoing specification, embodiments of the disclosure have been described with reference to specific exemplary embodiments thereof. It will be evident that various modifications may be made thereto without departing from the broader spirit and scope of the disclosure as set forth in the following claims. The specification and drawings are, accordingly, to be regarded in an illustrative sense rather than a restrictive sense.

What is claimed is:

1. A method performed within an integrated circuit, the method comprising:
receiving an input feature map at a first layer of a hardware-based neural network model having a plurality of layers implemented within an integrated circuit, wherein the input feature map is represented by integers of a first bit width; and
for each of a plurality of channels associated with the input feature map,
determining, based on a meta file associated with the neural network model, a set of quantization parameters associated with the channel, wherein the set of quantization parameters specifies a range for integers of the first bit width and a type of integers of a second bit width, and
quantizing, based on the set of quantization parameters, the input feature map at the channel from a first set of integers of the first bit width to a second set of integers of the second bit width.

2. The method of claim 1, wherein the first bit width comprises 32 bits and the second bit width comprises 8 bits.

3. The method of claim 1, wherein at least two of the channels are associated with different quantization parameters.

4. The method of claim 1, wherein at least two of the layers of the neural network model are associated with different quantization parameters.

5. The method of claim 1, further comprising:
for each of the channels of the input feature map received at the first layer,
determining weights and bias associated with the channel from the meta file, wherein the weights and the bias have been quantized offline to integers of the second bit width, and
generating, from the first layer, an output feature map represented by a third set of integers of the first bit width based on the quantized feature map, the quantized weights, and the quantized bias associated with the channel.

6. The method of claim 5, further comprising re-quantizing the output feature map from the third set of integers of the first bit width to a fourth set of integers of the second bit width before providing the output feature map as an input feature map to a second layer of the neural network model.

7. The method of claim 5, wherein at least two of the channels are associated with different weights and bias.

8. The method of claim 1, wherein quantizing the input feature map at each channel includes mapping each of the first set of integers of the first bit width to an integer in the second set of integers of the second bit width based on the set of quantization parameters.

9. An integrated circuit, comprising:
scaling logic configured to
receive an input feature map at a first layer of a hardware-based neural network model having a plurality of layers, wherein the input feature map is represented by integers of a first bit width, and
for each of a plurality of channels associated with the input feature map,
determine, based on a meta file associated with the neural network model, a set of quantization parameters associated with the channel, wherein the set of quantization parameters specifies a range for integers of the first bit width and a type of integers of a second bit width, and
quantize, based on the set of quantization parameters, the input feature map at the channel from a first set of integers of the first bit width to a second set of integers of the second bit width; and
a plurality of multiply-accumulate (MAC) units to perform data processing operations on the quantized input feature map.

10. The integrated circuit of claim 9, wherein the first bit width comprises 32 bits and the second bit width comprises 8 bits.

11. The integrated circuit of claim 9, wherein at least two of the channels are associated with different quantization parameters.

12. The integrated circuit of claim 9, wherein at least two of the layers of the neural network model are associated with different quantization parameters.

13. The integrated circuit of claim 9, wherein the scaling logic is further configured to:
for each of the channels of the input feature map received at the first layer,
determine weights and bias associated with the channel from the meta file, wherein the weights and the bias have been quantized offline to integers of the second bit width; and
generate, from the first layer, an output feature map represented by a third set of integers of the first bit width based on the quantized feature map, the quantized weights, and the quantized bias associated with the channel.

14. The integrated circuit of claim 13, wherein the scaling logic is to re-quantize the output feature map from the third set of integers of the first bit width to a fourth set of integers of the second bit width before providing the output feature map as an input feature map to a second layer of the neural network model.

15. The integrated circuit of claim 13, wherein at least two of the channels are associated with different weights and bias.

16. The integrated circuit of claim 9, wherein quantizing the input feature map at each channel includes mapping each of the first set of integers of the first bit width to an integer in the second set of integers of the second bit width based on the set of quantization parameters.

17. A computer-implemented method for quantizing a neural network model, the method including:
extracting a subset of data from a training data set, wherein the training data set includes a first subset used to train the neutral network model and a second subset used to validate a first neural network model represented by floating point values;
performing a plurality of inferences on the extracted subset of data using the first neural network model, the first neural network model having a plurality of layers and each of the layers including a plurality of channels;
quantizing the first neural network model to generate a second neural network model represented by integer values; and
generating a set of quantization metadata for each of the channels for each of the layers, wherein the second neural network model can be deployed in an integrated circuit to perform data classification operations in integers, and wherein the quantization metadata is utilized to scale data generated in each of the channels of each layer of the second neural network model.

18. The method of claim 17, further comprising generating a distribution of floating point values at each of the plurality of channels based on the plurality of inferences.

19. The method of claim 18, further comprising: for each of the plurality of channels of each layer of the first neural network model,
removing one or more outlier values based on a predetermined percentage from each end of the distribution of floating values;
determining a maximum floating-point value and a minimum floating-point value from the corresponding distribution;
determining a maximum integer value of a first bit width and a minimum integer value of the first bit width that respectively correspond to the maximum floating-point value and the minimum floating-point value; and
constructing a set of quantization parameters for the channel using the maximum integer value, the maximum floating-point value, the minimum floating-point value, the minimum integer value, and an integer type of a second bit width.

20. The method of claim 17, wherein the training data set includes a first subset used to train the neutral network model and a second subset used to validate a first neural network model represented by floating point values.
